(19) United States
(12) Patent Application Publication
(10) Pub. No.: US 2025/0304769 A1
(43) Pub. Date: Oct. 2, 2025

(54) COMPOSITION, SHEET AND METHOD FOR PRODUCING SAME

(71) Applicant: DAIKIN INDUSTRIES, LTD., Osaka (JP)

(72) Inventors: Shingo Okuno, Osaka (JP); Yuki Ueda, Osaka (JP); Kyohei Sawaki, Osaka (JP); Moe Hosokawa, Osaka (JP); Yoshito Tanaka, Osaka (JP); Akiyoshi Yamauchi, Osaka (JP); Yosuke Kishikawa, Osaka (JP)

(73) Assignee: DAIKIN INDUSTRIES, LTD., Osaka (JP)

(21) Appl. No.: 19/235,767

(22) Filed: Jun. 12, 2025

Related U.S. Application Data
(63) Continuation of application No. PCT/JP2023/044422, filed on Dec. 12, 2023.

(30) Foreign Application Priority Data
Dec. 13, 2022 (JP) 2022-198841
Nov. 2, 2023 (JP) 2023-188804

(51) Int. Cl. C08K 9/02; B32B 15/085; B32B 15/20; B32B 27/32; C08J 5/18

(52) U.S. Cl. CPC C08K 9/02; B32B 15/085; B32B 15/20; B32B 27/322; C08J 5/18; B32B 2250/02; B32B 2311/12; B32B 2457/08; C08J 2327/18; C08K 2201/005

(57) ABSTRACT

A composition for obtaining a sheet with a low linear expansion coefficient while maintaining electrical characteristics, a sheet made of the composition, and a method for producing the same are provided. The composition contains a fluororesin particle and a filler, with a filler content of 67 to 96.5 mass % in the total amount of the fluororesin particle and the filler. The sheet or film is made of a composition containing a fluororesin particle and a filler, with a filler content of 67 to 96.5 mass % in the total amount of the fluororesin particle and the filler.

### CROSS REFERENCE TO RELATED APPLICATIONS

This application is a Rule 53(b) Continuation of International Application No. PCT/JP2023/044422 filed on Dec. 12, 2023, claiming priority based on Japanese Patent Application No. 2022-198841 filed on Dec. 13, 2022 and Japanese Patent Application No. 2023-188804 filed on Nov. 2, 2023, the respective disclosures of which are incorporated herein by reference in their entirety.

### TECHNICAL FIELD

The present invention relates to a composition, a sheet and a method for producing the same.

### BACKGROUND ART

A high-frequency printed wiring board with a low transmission loss has been required. In such a high-frequency printed wiring board, use of a fluororesin film is known (Patent Literature 1, etc.). Further, use of a fluororesin compounded with a filler as wiring board material is described in Patent Literature 2 to 4.

### CITATION LIST

### Patent Literature

Patent Literature 1: Japanese Patent Laid-Open No. 2015-8260
Patent Literature 2: Japanese Patent Laid-Open No. S63-259907
Patent Literature 3: International Publication No. WO 2021/024883
Patent Literature 4: International Publication No. WO 2021/235460

### SUMMARY

The present disclosure relates to a composition containing a fluororesin particle and a filler, with a filler content of 67 to 96.5 mass % in the total amount of the fluororesin particle and the filler.

### DESCRIPTION OF EMBODIMENTS

The present disclosure is described in detail as follows.

Many studies have been conducted on compositions including a fluororesin compounded with a filler.

On the other hand, in the field of high-frequency printed wiring boards, performance such as low dielectric constant, low loss and low expansion, has been increasingly required at higher levels in recent years.

In the present disclosure, a composition with a low linear expansion coefficient is obtained by increasing the filler content. The composition of the present disclosure comprises a fluororesin particle and a filler, with a filler content of 67 to 96.5 mass % in the total amount of the fluororesin particle and the filler.

With such a compounded amount, a sheet having excellent performance, i.e., a low linear expansion coefficient while maintaining electrical characteristics such as a low dielectric constant and a low loss, can be provided.

In production of a sheet from a mixed composition of a fluororesin and a filler, conventionally a processing aid is added to the composition, and the mixture is paste extruded and rolled into a sheet. In this method, in the case of a high filler content, a sheet cannot be formed due to difficulty of extrusion of the paste.

In the present disclosure, it has been found that even a composition with a high filler content (67 to 96.5 mass %) can be formed into a sheet by powder rolling forming. Thereby, as described above, a composition with a low linear expansion coefficient can be obtained by increasing the filler content, and further, a fluororesin sheet having a low linear expansion coefficient can be provided while maintaining electrical characteristics.

The composition of the present disclosure contains a fluororesin particle and a filler, with a filler content of 67 to 96.5 mass % in the total amount of the fluororesin particle and the filler.

The lower limit of the filler content is more preferably 68 mass % or more, still more preferably 70 mass % or more, and most preferably 75 mass % or more. The upper limit of the filler compounding is preferably 90 mass % or less, and still more preferably 85 mass % or less. Such a content is preferred in terms of lowering the linear expansion coefficient while maintaining electrical characteristics. In the case where the filler content is less than the lower limit, the linear expansion coefficient increases, and in the case where the content is more than the upper limit, the sheet becomes brittle and formability deteriorates. In addition, an excessively low linear expansion coefficient is not preferred, and 75 to 85 mass % is most preferred from the viewpoint of having about the same linear expansion coefficient as that of a metal to be laminated, for example, a copper foil.

### (Filler)

The filler that can be used in the present disclosure is not limited, and examples thereof include one or more organic fillers selected from aramid fiber, polyphenyl ester, polyphenylene sulfide, polyimide, modified polyimide, polyether ether ketone, polyphenylene, polyamide and a wholly aromatic polyester resin, and one or more inorganic fillers selected from ceramics, talc, mica, aluminum oxide, zinc oxide, tin oxide, titanium oxide, silicon oxide, calcium carbonate, calcium oxide, magnesium oxide, potassium titanate, glass fibers, glass chips, glass beads, silicon carbide, calcium fluoride, boron nitride, barium sulfate, molybdenum disulfide and potassium carbonate whiskers. Two or more of these may be used in combination.

Among these, a filler containing silica, titanium oxide, magnesium oxide, or a combination thereof is particularly preferred. These fillers are preferred, because due to having a low linear expansion coefficient and a low dielectric tangent, the linear expansion coefficient and the dielectric tangent (Df) of a composition or sheet processed therefrom can be controlled to be low.

The shape of the filler is not limited, and a spherical shape is particularly preferred. A spherical shape is preferred in terms of easiness of uniform processing during drilling, and low transmission loss with a small specific surface area. In particular, use of a spherical silica particle is most preferred.

The spherical filler means that the particle shape is close to a true sphere. Specifically, the sphericity is preferably 0.80 or more, more preferably 0.85 or more, still more preferably 0.90 or more, and most preferably 0.95 or more. The sphericity is calculated as follows. An SEM photograph of a particle is observed to determine the area and the perimeter of the particle, from which the sphericity is calculated as a value: (Sphericity)={4π×(Area)/(Perimeter)²}. The closer to 1, the closer to the true sphere. Specifically, an average value measured for 100 particles with an image processing device (FPIA-3000, manufactured by Spectris Co., Ltd.) is employed.

In the present disclosure, it is preferable that the filler have an average particle size of 0.1 to 10 μm. The average particle size is D50 value measured by a laser diffraction-type particle size distribution analyzer. With an average particle size of less than 0.1 μm, due to occurrence of filler aggregation, insufficient effects tend to be obtained. With an average particle size of more than 10 μm, the sheet tends to be hardly formed into a thin film.

It is preferable that the spherical silica particles used in the present disclosure have a D90/D10 of 2 or more (preferably 2.3 or more, 2.5 or more) and a D50 of 10 μm or less in integration of the volume from the smaller particle size. Furthermore, it is preferable that D90/D50 be 1.5 or more (more preferably 1.6 or more). It is preferable that D50/D10 be 1.5 or more (more preferably 1.6 or more). These allow spherical silica particles with a smaller particle size to enter a space among spherical silica particles with a larger particle size, so that excellent filling property and high fluidity can be achieved. In particular, a particle size distribution having a higher frequency on the smaller particle size-side compared to a Gaussian curve is preferred. The particle size can be measured by a laser diffraction scattering-type particle size distribution measurement apparatus. It is also preferable that coarse particles having a predetermined particle size or more be removed using a filter or the like.

A fluororesin sheet is heated under atmosphere at 600° C. for 30 minutes to burn off the fluororesin. After the spherical silica particle is taken out, each of the parameters may also be measured by the method described above.

The spherical silica particle for use may be a commercially available silica particle that satisfies the properties described above. Examples of the commercially available silica particle include Denka fused silica FB Grade (manufactured by Denka Co., Ltd.), Denka fused silica SFP Grade (manufactured by Denka Co., Ltd.), Excelica (manufactured by Tokuyama Corporation), high-purity synthetic spherical silica particle Admafine (manufactured by Admatechs Co., Ltd.), Admanano (manufactured by Admatechs Co., Ltd.), and Admafuse (manufactured by Admatechs Co., Ltd.).

The titanium oxide and magnesium oxide described above have a higher relative dielectric constant (Dk) than silica, and can be added to adjust the relative dielectric constant (Dk). Examples of the commercially available titanium oxide include CR-EL (manufactured by Ishihara Sangyo Kaisha, Ltd.) and HT0210 (manufactured by Toho Titanium Co., Ltd.). Examples of the commercially available magnesium oxide include RF-10CS and RF-10C-45 μm (manufactured by Ube Material Industries, Ltd.).

The filler is preferably surface-treated. Being subjected to surface treatment in advance, silica particle is prevented from aggregation, so that the silica particle can be well dispersed in a resin composition.

In order to perform the surface treatment, the type and the amount of surface-treating agent are appropriately selected.

The amount of the surface-treating agent is preferably 0.2 mass % or more, and more preferably 0.5 mass % or more from the viewpoints of lowering the dielectric constant, the dielectric tangent, and the linear expansion coefficient. The amount of the surface-treating agent is preferably 5 mass % or less.

The surface treatment is not limited, and any known one may be used. Specific examples of the treatment include treatment with a silane coupling agent such as epoxysilane, aminosilane, isocyanate silane, vinylsilane, acrylic silane, hydrophobic alkylsilane, phenyl silane, and fluorinated alkylsilane having a reactive functional group, plasma processing, and fluorination treatment.

Specific examples of the silane coupling agent include an epoxy silane such as γ-glycidoxypropyl triethoxysilane and β-(3,4-epoxycyclohexyl)ethyltrimethoxysilane, an amino silane such as aminopropyltriethoxysilane and N-phenyl aminopropyl trimethoxysilane, an isocyanate silane such as 3-isocyanatepropyltrimethoxysilane and 3-isocyanatepropyltriethoxysilane, a vinyl silane such as vinyltrimethoxysilane, and an acrylic silane such as acryloxy trimethoxysilane.

In the present disclosure, it is preferable to use a filler of which surface is coated with a silane coupling agent, among those surface-treated.

### (Fluororesin Particle)

The composition of the present disclosure contains a fluororesin particle. The fluororesin particle has low dielectric properties and can therefore be suitably used for the purpose of the present disclosure.

It is preferable that the average particle size of the fluororesin particle be 0.05 to 1, 000 μm. The lower limit of the average particle size of the fluororesin particle is more preferably 0.07 μm or more, and still more preferably 0.1 μm or more. The upper limit of the average particle size of the fluororesin particle is preferably 700 μm or less, and still more preferably 500 μm or less.

Use of such a particle has an advantage of excellent formability and dispersibility. The average particle size is a value measured in accordance with ASTM D 4895.

It is preferable that the volume-based cumulative 50% size of the fluororesin particle be 0.05 to 40 μm. The lower limit of the volume-based cumulative 50% size of the fluororesin particle is more preferably 0.7 μm or more, and still more preferably 1 μm or more. The upper limit of the volume-based cumulative 50% size of the fluororesin particle is preferably 35 μm or less, and still more preferably 30 μm or less.

Use of such a particle has an advantage of excellent formability and dispersibility. The volume-based cumulative 50% size is a value measured by a laser diffraction-type particle size distribution analyzer.

The fluororesin particle for use in the present disclosure is not limited, and examples thereof include polytetrafluoroethylene (PTFE), tetrafluoroethylene [TFE]/hexafluoropropylene [HFP] copolymer [FEP], TFE/alkyl vinyl ether copolymer [PFA], TFE/HFP/alkyl vinyl ether copolymer [EPA], TFE/chlorotrifluoroethylene [CTFE] copolymer, TFE/ethylene copolymer [ETFE], polyvinylidene fluoride [PVdF], and tetrafluoroethylene with a molecular weight of 300, 000 or less [LMW-PTFE]. One type thereof may be used, or two or more types may be mixed.

It is preferable that the fluororesin particle for use in the present disclosure be non melt-processible.

The term “non melt-processible” means that a resin has insufficient fluidity even when heated to the melting point or more, and cannot be molded by melting generally used for resins. PTFE falls into this category.

From the viewpoint of low dielectric properties, PTFE is particularly preferred. PTFE having fibrillation properties is preferred. PTFE having fibrillation properties allows non sintered polymer particles to be paste extruded or formed by powder rolling.

The modified PTFE contains a TFE unit based on TFE and a modifying monomer unit based on a modifying monomer. The modifying monomer unit is a part of the molecular structure of modified PTFE, which is a part derived from the modifying monomer. The modified PTFE contains a modifying monomer unit in an amount of preferably 0.001 to 0.500 mass %, more preferably 0.01 to 0.30 mass % of the total monomer units. The total monomer units are the part derived from all the monomers in the molecular structure of the modified PTFE.

The modifying monomer is not limited as long as it can be copolymerized with TFE, and examples thereof include perfluoro-olefin such as hexafluoropropylene (HFP); chlorofluoro-olefin such as chlorotrifluoroethylene (CTFE); hydrogen-containing fluoroolefin such as trifluoroethylene and vinylidene fluoride (VDF); perfluoro vinyl ether; and perfluoro alkyl ethylene (PFAE) and ethylene. One type or plural types of modifying monomers may be used.

The perfluoro vinyl ether is not limited, and examples thereof include an unsaturated perfluoro compound represented by the following general formula (1):

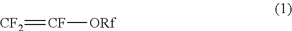

wherein, Rf represents a perfluoro organic group.

In the present specification, the perfluoro organic group is an organic group of which all the hydrogen atoms bonded to a carbon atom are replaced with fluorine atoms. The perfluoro organic group may have an ether oxygen.

Examples of the perfluoro vinyl ether include perfluoro (alkyl vinyl ether) (PAVE) with Rf in the general formula (1) being a perfluoroalkyl group having 1 to 10 carbon atoms. The number of carbon atoms of the perfluoroalkyl group is preferably 1 to 5. Examples of the perfluoroalkyl group in PAVE include a perfluoromethyl group, a perfluoroethyl group, a perfluoropropyl group, a perfluorobutyl group, a perfluoropentyl group, and a perfluorohexyl group. As PAVE, perfluoropropyl vinyl ether (PPVE) and perfluoromethyl vinyl ether (PMVE) are preferred.

The perfluoro alkyl ethylene (PFAE) is not limited, and examples thereof include perfluoro butyl ethylene (PFBE), and perfluoro hexyl ethylene (PFHE).

As the modifying monomer in the modified PTFE, at least one selected from the group consisting of HFP, CTFE, VDF, PAVE, PFAE and ethylene is preferred.

In the present disclosure, it is preferable that a fluororesin sheet be formed from a non melt-processible fluororesin by a forming method such as fibrillation. The forming method will be described later.

It is preferable that the PTFE have a standard specific gravity (SSG) of 2.0 to 2.3. From such PTFE, a PTFE film with high strength (cohesion force and piercing strength per unit thickness) tends to be easily obtained. PTFE with a large molecular weight has long molecular chains, so that a structure in which the molecular chains are regularly arranged is hardly formed. In that case, the length of an amorphous portion increases, so that the degree of entanglement among molecules increases. It is presumed that with a high degree of entanglement among molecules, a PTFE film is less likely to deform under an applied load, so that excellent mechanical strength can be exhibited. Further, use of PTFE with a large molecular weight makes it easier to obtain a PTFE film with a small average pore size.

The lower limit of the SSG is more preferably 2.05, and still more preferably 2.1. The upper limit of the SSG is more preferably 2.25, and still more preferably 2.2.

Standard specific gravity (SSG) is measured as follows. A sample is prepared in accordance with ASTM D-4895-89 and the specific gravity of the resulting sample is measured by water displacement method.

It is preferable that the PTFE have a refractive index in the range of 1.2 to 1.6. Having such a refractive index is preferred in terms of low dielectric constant. The refractive index in the range is achieved by a method of adjusting the polarizability or the flexibility of the main chain, and other methods. The lower limit of the refractive index is more preferably 1.25, still more preferably 1.30, and most preferably 1.32. The upper limit of the refractive index is more preferably 1.55, more preferably 1.50, and most preferably 1.45.

The refractive index is a value measured with a refractometer (Abbemat 300).

The particulate PTFE contains a polytetrafluoroethylene resin having a secondary particle size of 500 μm or more in an amount of preferably 50 mass % or more, more preferably 80 mass % or more. With a content of PTFE having a secondary particle size of 500 μm or more in the range, an advantage in terms of producing a sheet with high strength is achieved.

Through use of PTFE with a secondary particle size of 500 μm or more, a sheet with lower resistance and high toughness can be obtained.

The lower limit of the secondary particle size is more preferably 300 μm, and still more preferably 350 μm. The upper limit of the secondary particle size is more preferably 700 μm or less, and still more preferably 600 μm or less. The secondary particle size may be determined, for example, by a sieving method.

Further, it is preferable that the PTFE have a maximum endothermic peak temperature (crystalline melting point) of 340±7° C.

The PTFE may be a low melting point PTFE having a maximum peak temperature of 338° C. or less on the endothermic curve of a crystalline melting curve measured by a differential scanning calorimeter, or a high melting point PTFE having a maximum peak temperature of 342° C. or more on the endothermic curve of a crystalline melting curve measured by a differential scanning calorimeter.

The low melting point PTFE particle is a particle produced by polymerization by emulsion polymerization method, and has the maximum endothermic peak temperature (crystalline melting point) described above, a dielectric constant (ε) of 2.08 to 2.2, and a dielectric tangent (tan δ) of 1.9×10⁻⁴ to 4.0×10⁻⁴. Examples of the commercially available product include Polyflon Fine Powder F201, F203, F205, F301 and F302 manufactured by Daikin Industries, Ltd., CD090 and CD076 manufactured by AGC Inc., and TF6C, TF62 and TF40 manufactured by DuPont.

The high melting point PTFE particle is also a particle produced by polymerization by emulsion polymerization method, and has the maximum endothermic peak temperature (crystalline melting point) described above, a dielectric constant (ε) of 2.0 to 2.1, and a dielectric tangent (tan δ) of 1.6×10⁻⁴ to 2.2×10⁻⁴, which are generally low. Examples of the commercially available product include Polyflon Fine Powder F104 manufactured by Daikin Industries, Ltd., CD1, CD141 and CD123 manufactured by AGC Inc., and TF6 and TF65 manufactured by DuPont.

It is preferable that the average particle size of the secondary aggregates of both PTFE particles be usually 250 to 2000 μm. In particular, granulated particles obtained by granulation with a solvent are preferred in terms of improved fluidity during filling a mold in the premolding.

PTFE having a particle shape that satisfies each of the parameters described above can be obtained by a conventional production method. For example, the production may be performed by following the production methods described in International Publication No. WO 2015-080291 and International Publication No. WO 2012-086710 or the like.

### (Composition)

The composition of the present disclosure contains the filler and fluororesin particle described above. If needed, the composition may contain a component other than the filler and the fluororesin particle, or may solely consist of the filler and the fluororesin particle. It is preferable that the content of components other than the filler and the fluororesin particle be 10 mass % or less relative to the total amount of the composition.

In particular, it is preferable that the composition substantially consist of a fluororesin particle and a filler. “Substantially consist of fluororesin particle and a filler” means that the content of components other than the filler and the fluororesin particle is 3 mass % or less relative to the total amount of the composition.

It is preferable that the composition of the present disclosure have a dielectric tangent of 0.0001 to 0.0015 at 10 GHz. With a dielectric tangent in the range, the composition is preferred in terms of achieving low loss.

### (Sheet)

The composition of the present disclosure is suitably used for forming a sheet.

The present disclosure also relates to a sheet made of a composition containing a fluororesin particle and a filler, with a filler content of 67 to 96.5 mass % in the total amount of the fluororesin particles and the filler.

It is preferable that the sheet have a thickness of 5 to 250 μm. The sheet of the present disclosure can adequately achieve its purpose even with a thin thickness. From such a viewpoint, the thickness is more preferably less than 200 μm, and still more preferably less than 150 μm.

It is preferable that the sheet of the present disclosure have a relative dielectric constant (Dk) at 10 GHz of 3.5 or less, a dielectric tangent (Df) of 0.0014 or less, and a linear expansion coefficient (CTE) of 40 ppm/K or less.

With these physical properties being satisfied, a sheet has performance with excellent electrical characteristics and a low linear expansion coefficient.

A relative dielectric constant (Dk) at 10 GHz of 3.5 or less is preferred in terms of having a low dielectric loss.

The upper limit of the relative dielectric constant (Dk) is more preferably 3.2, and still more preferably 3.1. The lower limit of the relative dielectric constant (Dk) is more preferably 2.0, and still more preferably 2.5.

A dielectric tangent (Df) of 0.0014 or less is preferred in terms of having a low dielectric loss.

The upper limit of the dielectric tangent (Df) is more preferably 0.0012, and still more preferably 0.0011. The lower limit of the dielectric tangent (Df) is more preferably 0.

The relative dielectric constant (Dk) and the dielectric tangent (Df) at 10 GHz in the present specification are determined through measurement of Dk and Df at 25° C. and 10 GHz using a split cylinder-type dielectric constant/dielectric tangent measuring device (manufactured by EM labs, Inc.).

A linear expansion coefficient (CTE) of 40 ppm/K or less is preferred in terms of producing a fluororesin sheet with low shrinkage and excellent dimensional stability. The upper limit of the linear expansion coefficient (CTE) is more preferably 35, and still more preferably 30. The lower limit of the linear expansion coefficient (CTE) is more preferably 5, and still more preferably 10.

The linear expansion coefficient in the present specification is determined by performing TMA measurement in a tensile mode using a TMA-7100 (manufactured by Hitachi High-Tech Science Corporation). A sheet is cut into a length of 20 mm and a width of 5 mm as a sample piece. The chuck distance is set to 10 mm. While applying a load of 49 mN at a heating rate of 2° C./min, the linear expansion coefficient is determined from the amount of displacement of the sample at 0 to 150° C.

### (Production Method of Sheet)

The sheet of the present disclosure may be produced through film formation using the fluororesin particle and the filler. It is preferable that the production method include powder rolling forming.

The present disclosure also relates to a production method of the sheet, including mixing the fluororesin particle and filler at a filler content of 67 to 96.5 mass % relative to the total amount of the fluororesin particle and filler to form a film.

As described above, it is preferable that a non melt-processible fluororesin be employed as the fluororesin for use in the sheet of the present disclosure. In the case of using such a fluororesin, it is preferable that powdered PTFE as raw material be fibrillated to achieve forming into a sheet shape.

Examples of the specific method for powder rolling forming include the following methods.

### (Powder Rolling Forming)

Powder rolling forming is a method of applying a shear force to a resin powder to be fibrillated, so that forming into a sheet shape is achieved. The method may include subsequent sintering of the formed sheet to obtain a formed article.

More specific examples of the production method include: a step (1) of applying a shear force to a raw material composition containing a fluororesin particle and a filler while mixing; a step (2) of forming the mixture obtained in the step (1) into a bulk form; and a step (3) of rolling the mixture in the bulk form obtained in the step (2) into a sheet form.

The production method may further include: a step (4) of sintering the resulting product in a sheet form at 200 to 400° C. for 1 to 60 minutes. Through changing the sintering temperature, the physical properties of the sheet can be controlled. For example, sintering at a low temperature of 345° C. or less allows the dielectric tangent to be reduced. Sintering at a high temperature of 350° C. or more allows the linear expansion coefficient to be reduced.

Alternatively, the step (2) may be omitted.

In the case where a sheet is formed by such powder rolling forming, it is preferable that a composition substantially consisting of a fluororesin particle and a filler be used for film formation.

Alternatively, it is preferable that a fluororesin particle and a filler only be mixed for the forming.

The stirring device for use in mixing in the step (1) is not limited, and the fluororesin particle and the filler may be mixed with a mixer or the like.

The stirring temperature is not limited, preferably 0 to 50° C., more preferably 10 to 30° C.

The stirring time period is not limited, preferably from 1 second to 1 hour, more preferably from 10 seconds to 10 minutes.

Further, in mixing, it is preferable that PTFE be partially fibrillated.

The device for rolling into a sheet in the step (3) is not limited, and may be any device capable of applying shearing to the powder mixture obtained in the step (1) or the mixture in a bulk form obtained in step (2) to make a sheet. Examples thereof include a powder rolling device, a powder film forming device, a roll press (two or three rolls), and a double belt press.

The temperature at which a sheet is formed is not limited, preferably 20 to 300° C., and more preferably 30 to 200° C.

### (Laminate)

The sheet of the present disclosure may be laminated with another substrate for use as a sheet for substrate for circuits.

The present disclosure also relates to a metal laminate having a metal layer and the fluororesin sheet described above as essential layers. The metal laminate may include a metal layer bonded to one or both sides of the fluororesin sheet described above. As described above, the sheet containing the fluororesin of the present disclosure is particularly suitably used for a printed wiring board, and therefore can be suitably used as such a metal laminate.

Examples of the metal layer include a copper foil, gold foil, silver foil, platinum foil and ruthenium foil. Among these, copper foil is preferred due to having a low conductor loss.

It is preferable that the copper foil have an Rz of 1.6 μm or less. The composition of the present disclosure has excellent adhesion to a copper foil having a high smoothness with Rz of 1.6 μm or less. Furthermore, the copper foil needs only to have Rz of 1.6 μm or less on at least the surface to be bonded to the fluororesin sheet, and the Rz value is not limited on surfaces that are not bonded to the fluororesin sheet.

The Rz is the sum of a value at the highest point (maximum peak height: Rp) and a value at the deepest point (maximum valley depth: Rv). The surface roughness is the ten-point average roughness specified in JIS-B0601. In the present specification, the Rz is a value measured for a measurement length of 4 mm by a surface roughness meter (trade name: Surfcom 470A, manufactured by Tokyo Seimitsu Co., Ltd.).

The thickness of the copper foil is not limited, preferably in the range of 1 to 100 μm, more preferably in the range of 5 to 50 μm, and still more preferably 9 to 35 μm.

The copper foil is not limited, and specific examples thereof include a rolled copper foil and an electrolytic copper foil.

The copper foil with Rz of 1.6 μm or less is not limited, and a commercially available product may be used. Examples of the commercially available copper foil with Rz of 1.6 μm or less include an electrolytic copper foil CF-T9DA-SV-18 (thickness: 18 μm, Rz: 0.85 μm) (manufactured by Fukuda Metal Foil and Powder Co., Ltd.).

The copper foil may be surface-treated to increase the adhesion strength with the sheet of the present disclosure.

In order to improve various properties, one or more layers selected from the group consisting of a heat-resisting treated layer, a rust-proofing treated layer, and a chromate-treated layer may be provided between the copper foil and the surface-treated layer. These layers may include a single layer or multiple layers.

The copper clad laminate of the present disclosure may further include a layer other than the copper foil and sheet.

In the metal clad laminate of the present disclosure, the metal layer may be formed on one or both sides of the sheet in a roll shape. Examples of the method for forming the metal layer include laminating (adhering) a metal foil to the surface of the sheet in a roll shape, vapor deposition, and plating. Examples of the method for laminating metal foil include hot pressing. Examples of the hot pressing temperature include a temperature in the range from the melting point of the dielectric film-150° C. to the melting point of the dielectric film+40° C. The hot pressing time period is, for example, 1 to 30 minutes. The hot pressing pressure in the production method may be 0.1 to 10 MPa.

### (Film)

In the present disclosure, the composition may be used to form a film. The present disclosure also relates to a film made of a composition containing a fluororesin particle and a filler, with a filler content of 67 to 96.5 mass % in the total amount of the fluororesin particle and the filler.

The film of the present disclosure may be obtained by applying a dispersion of powder containing a fluororesin particle and a filler dispersed in a liquid medium onto a substrate, drying the applied one, and then heating the dried applied one.

The use of the metal laminate of the present disclosure is not limited, and the metal laminate is used, for example, as a substrate for circuits. The present disclosure also relates to a substrate for circuits having the metal laminate described above.

The substrate for circuits is a plate-shaped component for electrically connecting electronic components such as semiconductors and capacitor chips, while disposing and fixing them in a limited space at the same time. The configuration of the substrate for circuits formed from the present metal laminate is not limited. The substrate for circuits may be any of a rigid circuit board, a flexible circuit board, and a rigid-flexible circuit board. The substrate for circuits may be any of a single-sided board circuit board, a double-sided circuit board, and a multilayer circuit board (such as a built-up circuit board). In particular, the substrate for circuits can be suitably used for flexible circuit boards and rigid circuit boards. In particular, the substrate for circuits can be suitably used as a high-frequency printed circuit board of 10 GHz or more.

The substrate for circuits is not limited, and may be produced from the metal laminate described above by a conventional method.

The laminate for circuit boards is also a laminate including a copper foil layer, the sheet described above, and further a substrate layer. The substrate layer is not limited, and preferably has a fabric layer made of glass fiber, and a resin film layer.

It is preferable that the fluororesin particle be non melt-processible.

It is preferable that the fluororesin particle be polytetrafluoroethylene (PTFE).

It is preferable that the polytetrafluoroethylene have a standard specific gravity (SSG) of 2.0 to 2.3.

It is preferable that the filler comprise silica, titanium oxide, magnesium oxide, or a combination thereof.

It is preferable that the filler have a surface coated with a silane coupling agent.

It is preferable that the filler be spherical.

It is preferable that the spherical filler have an average particle size of 0.1 to 10 μm.

It is preferable that the fluororesin particle have an average particle size of 0.05 to 1,000 μm.

The present disclosure also relates to a sheet or film made of a composition comprising a fluororesin particle and a filler, with a filler content of 67 to 96.5 mass % in the total amount of the fluororesin particle and the filler.

It is preferable that a thickness of the sheet or film be 5 to 250 μm.

It is preferable that the relative dielectric constant (Dk) at 10 GHz be 3.5 or less, the dielectric tangent (Df) be 0.0014 or less, and the linear expansion coefficient (CTE) be 40 ppm/K or less.

The present disclosure also relates to a method for producing the sheet or film, comprising mixing a fluororesin particle and a filler at a filler content of 67 to 96.5 mass % in the total amount of the fluororesin particle and the filler, and forming a film.

It is preferable that the film be formed using a composition substantially consisting of a fluororesin particle and a filler.

The present disclosure also relates to a metal laminate including a metal layer and the sheet or film as essential layers.

It is preferable that the metal layer be a copper foil.

The present disclosure also relates to a substrate for circuits having the metal laminate.

### EXAMPLES

The present disclosure is specifically described with reference to Examples as follows. In the following Examples, unless otherwise specified, “part” and “%” represent “part by mass” and “mass %”, respectively.

### Example 1 to Example 13

### (Powder Rolling Forming)

Each of the fluororesin particle (PTFE) and spherical silica was weighed, such that the spherical silica content was the amount shown in Table 1, and the mixture was stirred at room temperature with a Wonder Crusher at memory 6 for 30 seconds twice.

The resulting mixture was rolled with two rolls (roll space: set to 100 μm, roll temperature: 100° C.) to obtain a sample with a film thickness of 130 μm, which was sintered at 340° C. or 360° C. for 15 minutes to obtain a sheet.

The spherical silica for use in each Example was SC6500-SQ (average particle size: 2.1 μm) produced by Admatechs Co., Ltd. or SC6500-SQ (average particle size: 2.1 μm) produced by Admatechs Co., Ltd., which was surface-treated with 3-aminopropyl triethoxysilane (treatment amount: 1 mass %) as shown in Table 1. In Example 13, SC6500-SQ (average particle size: 2.1 μm) produced by Admatechs Co., Ltd. was surface-treated with 3-isocyanate propyltriethoxysilane (treatment amount: 0.3 mass %) for use.

The fluororesin particle (PTFE) for use in each Example has the following properties.
Average particle size: 500 μm
Apparent density: 460 g/L
Standard specific gravity: 2.17

### Comparative Example 1, Comparative Example 3, Comparative Example 7, and Comparative Example 8

### (Paste Extrusion)

The fluororesin particle (PTFE) and the spherical silica were weighed in prescribed amounts in the proportion shown in Table 2 and mixed in a mixer in the presence of dry ice. The temperature during mixing was-10° C. or less.

To the resulting mixture, oil (Isopar H) was added in an amount of 20% to be mixed, and the mixture was aged for about 5 hours.

The aged composition was preformed under a pressure of 3 MPa, and the preformed article was extruded under conditions at 40° C. and 50 mm/min to obtain an extrusion sample. The extrusion sample was rolled with two rolls to obtain a sample with a film thickness of 125 μm, which was then dried at 200° C. for 2 hours and sintered at 340° C. or 360° C. for 15 minutes to obtain a sheet.

### Comparative Example 2, and Comparative Example 4 to Comparative Example 6

### (Powder Rolling Forming)

The fluororesin particle (PTFE) and the spherical silica were weighed in prescribed amounts in the proportion shown in Table 2, and the rest of the procedure was the same as in Examples to obtain a sheet.

Each of the resulting sheets was evaluated based on the following criteria.

### [Dk and Df]

Dk and Df at 25° C. and 10 GHz were measured using a split cylinder-type dielectric constant/dielectric tangent measuring device (manufactured by EM labs, Inc.).

### [CTE (Linear Expansion Coefficient)]

TMA measurements were performed in a tensile mode using a TMA-7100 (manufactured by Hitachi High-Tech Science Corporation). A sheet cut into a length of 20 mm and a width of 5 mm was used as a sample piece. The chuck distance was set to 10 mm, and the CTE (linear expansion coefficient) was determined from the amount of displacement of the sample at a heating rate of 2° C./min from 0 to 150° C. while applying a load of 49 mN.

### [Formability]

The formability was evaluated as good, fair or poor according to the following criteria.
Good: A sheet was optionally formed without wrinkles or cracking.
Fair: Wrinkles occurred in the sheet.
Poor: Cracks occurred in the sheet.

The results are shown in Table 1 and Table 2.

TABLE 1

| | | | Silene coupling agent/ | Amount of |
|---|---|---|---|---|
| | Forming method | Type of silica | Surface treatment | silica (%) |
| Example 1 | Powder rolling forming | SC6500-SQ | | 75 |
| Example 2 | Powder rolling forming | SC6500-SQ | | 90 |
| Example 3 | Powder rolling forming | SC6500-SQ | | 95 |
| Example 4 | Powder rolling forming | SC6500-SQ | 3-aminopropyl triethoxysilane (1%) | 75 |
| Example 5 | Powder rolling forming | SC6500-SQ | 3-aminopropyl triethoxysilane (1%) | 90 |
| Example 6 | Powder rolling forming | SC6500-SQ | 3-aminopropyl triethoxysilane (1%) | 95 |
| Example 7 | Powder rolling forming | SC6500-SQ | | 75 |
| Example 8 | Powder rolling forming | SC6500-SQ | | 90 |
| Example 9 | Powder rolling forming | SC6500-SQ | | 95 |
| Exemple 10 | Powder rolling forming | SC6500-SQ | 3-aminopropyl triethoxysilane (1%) | 75 |
| Example 11 | Powder rolling forming | SC6500-SQ | 3-aminopropyl triethoxysilane (1%) | 90 |
| Example 12 | Powder rolling forming | SC6500-SQ | 3-aminopropyl triethoxysilane (1%) | 95 |
| Exemple 13 | Powder rolling forming | SC6500-SQ | 3-isocyanatepropyltriethoxysilane (0.3%) | 75 |

| | Sintering | | | | |
|---|---|---|---|---|---|
| | temperature | | | CTE | |
| | (° C.) | Dk (10 GHz) | Df (10 GHz) | (ppm/K) | Formability |
| Example 1 | 340 | 2.62 | 0.0007 | 35 | good |
| Example 2 | 340 | 2.58 | 0.0007 | 18 | good |
| Example 3 | 340 | 2.52 | 0.0009 | 15 | good |
| Example 4 | 340 | 2.58 | 0.0006 | 22 | good |
| Example 5 | 340 | 2.53 | 0.0006 | 9 | good |
| Example 6 | 340 | 2.43 | 0.0006 | 8 | good |
| Example 7 | 360 | 2.63 | 0.0012 | 33 | good |
| Example 8 | 360 | 2.59 | 0.0013 | 14 | good |
| Example 9 | 360 | 2.46 | 0.001 | 12 | good |
| Exemple 10 | 360 | 2.51 | 0.0009 | 15 | good |
| Example 11 | 360 | 2.47 | 0.001 | 9 | good |
| Example 12 | 360 | 2.37 | 0.0008 | 8 | good |
| Exemple 13 | 340 | 2.63 | 0.0007 | 27 | good |

TABLE 2

| | | | Silane coupling agent/ | Amount of |
|---|---|---|---|---|
| | Forming method | Type of silica | Surface treatment | silica (%) |
| Comparative Example 1 | Paste extrusion | SC6500-SQ | | 50 |
| Comparative Example 2 | Powder rolling forming | SC6500-SQ | | 97 |
| Comparative Example 3 | Paste extrusion | SC6500-SQ | 3-aminopropyl triethoxysilane (1%) | 55 |
| Comparative Example 4 | Powder rolling forming | SC6500-SQ | 3-aminopropyl triethoxysilane (1%) | 97 |
| Comparative Example 5 | Powder rolling forming | SC6500-SQ | | 97 |
| Comparative Example 6 | Powder rolling forming | SC6500-SQ | 3-aminopropyl triethoxysilane (1%) | 97 |
| Comparative Example 7 | Paste extrusion | SC6500-SQ | | 85 |
| Comparative Example 8 | Paste extrusion | SC6500-SQ | 3-aminopropyl triethoxysilane (1%) | 65 |

| | Sintering | | | | |
|---|---|---|---|---|---|
| | temperature | | | | |
| | (° C.) | Dk (10 GHz) | Df (10 GHz) | CTE (ppm/K) | Formability |
| Comparative Example 1 | 340 | 2.65 | 0.0008 | 76 | good |
| Comparative Example 2 | 340 | unmeasurable | unmeasurable | unmeasurable | poor |
| Comparative Example 3 | 340 | 2.59 | 0.0006 | 81 | good |
| Comparative Example 4 | 340 | unmeasurable | unmeasurable | unmeasurable | poor |
| Comparative Example 5 | 360 | unmeasurable | unmeasurable | unmeasurable | poor |
| Comparative Example 6 | 360 | unmeasurable | unmeasurable | unmeasurable | poor |
| Comparative Example 7 | 360 | unmeasurable | unmeasurable | unmeasurable | fair |
| Comparative Example 8 | 360 | unmeasurable | unmeasurable | unmeasurable | fair |

The results described above show that the sheet disclosed herein has excellent performance in terms of low linear expansion coefficient.

### INDUSTRIAL APPLICABILITY

The sheet of the present disclosure is particularly suitable for use in a high-frequency printed circuit board.

1. A composition comprising a fluororesin particle and a filler, with a filler content of 75 to 96.5 mass % in the total amount of the fluororesin particle and the filler.

2. The composition according to claim 1, wherein the fluororesin particle is non melt-processible.

3. The composition according to claim 1, wherein the fluororesin particle is polytetrafluoroethylene (PTFE).

4. The composition according to claim 3, wherein the polytetrafluoroethylene has a standard specific gravity (SSG) of 2.0 to 2.3.

5. The composition according to claim 1, wherein the filler comprises silica, titanium oxide, magnesium oxide, or a combination thereof.

6. The composition according to claim 1, wherein the filler has a surface coated with a silane coupling agent.

7. The composition according to claim 1, wherein the filler is spherical.

8. The composition according to claim 7, wherein the spherical filler has an average particle size of 0.1 to 10 μm.

9. The composition according to claim 1, wherein the fluororesin particle has an average particle size of 0.05 to 1,000 μm.

10. A sheet or film made of a composition comprising a fluororesin particle and a filler, with a filler content of 75 to 96.5 mass % in the total amount of the fluororesin particle and the filler.

11. The sheet or film according to claim 10, a thickness of 5 to 250 μm.

12. The sheet or film according to claim 10, wherein the sheet or film has a relative dielectric constant (Dk) at 10 GHz of 3.5 or less, a dielectric tangent (Df) of 0.0014 or less, and a linear expansion coefficient (CTE) of 40 ppm/K or less.

13. A method for producing a sheet or film, comprising mixing a fluororesin particle and a filler, with a filler content of 75 to 96.5 mass % in the total amount of the fluororesin particle and the filler, and forming a film.

14. The method for producing a sheet or film according to claim 13, wherein the film is formed using a composition substantially consisting of a fluororesin particle and a filler.

15. A metal laminate comprising a metal layer and the sheet or film according to claim 10 as essential layers.

16. The metal laminate according to claim 15, wherein the metal layer is a copper foil.

17. A substrate for circuits comprising the metal laminate according to claim 15.
